(19) United States
(12) Patent Application Publication
(10) Pub. No.: US 2025/0022720 A1
(43) Pub. Date: Jan. 16, 2025

(54) TEMPERATURE CONTROL METHOD FOR SEMICONDUCTOR PROCESS

(71) Applicant: Beijing E-Town Semiconductor Technology Co., Ltd., Beijing (CN)

(72) Inventors: Jianmin JI, Beijing (CN); Wenyi LI, Beijing (CN)

(21) Appl. No.: 18/763,990

(22) Filed: Jul. 3, 2024

(30) Foreign Application Priority Data
Jul. 14, 2023 (CN) 202310871362.7

(51) Int. Cl. H01L 21/324; H01L 21/66

(52) U.S. Cl. CPC H01L 21/324; H01L 22/12

(57) ABSTRACT

Provided is a temperature control method for semiconductor process, comprising: setting a first measurement point of a first point distribution in a first process device to measure a temperature in the first process device; and setting a second measurement point of a second point distribution in a second detection device to measure a target parameter; wherein the first point distribution comprises a concentric circle-shaped dot matrix with unequal radial spacings; and the second point distribution has a concentric circle-shaped dot matrix corresponding to the first point distribution.

### CROSS-REFERENCE TO RELATED APPLICATIONS

The present application claims priority to Chinese Patent Application No. CN202310871362.7, filed with the China National Intellectual Property Administration on Jul. 14, 2023, the disclosure of which is hereby incorporated herein by reference in its entirety.

### TECHNICAL FIELD

The present disclosure relates to the field of semiconductor manufacturing, and in particular to a temperature control method for semiconductor process.

### BACKGROUND

The semiconductor process usually uses the rapid thermal annealing process, and the rapid thermal annealing devices usually include normal pressure annealing devices and low pressure annealing devices. In semiconductor manufacturing, based on different applications, the temperature range of the thermal annealing process is usually between 200° C. and 1250° C., belonging to a high-temperature process device. The temperature is an important parameter in the rapid thermal annealing device, and especially in the advanced manufacturing process, the temperature deviation is usually required to be less than 1° C.

### SUMMARY

The present disclosure provides a temperature control method for semiconductor process, to monitor the process uniformity of the entire semiconductor workpiece and accurately compensate the process temperature.

According to one aspect of the present disclosure, provided is a temperature control method for semiconductor process, including: setting a first measurement point of a first point distribution in a first process device to measure a temperature in the first process device; and setting a second measurement point of a second point distribution in a second detection device to measure a target parameter; where the first point distribution includes a concentric circle-shaped dot matrix with unequal radial spacings; and the second point distribution has a concentric circle-shaped dot matrix corresponding to the first point distribution.

It should be understood that the content described in this part is not intended to identify critical or essential features of embodiments of the present disclosure, nor is it used to limit the scope of the present disclosure. Other features of the present disclosure will be easily understood through the following description.

### BRIEF DESCRIPTION OF THE DRAWINGS

The accompanying drawings are used to better understand the present solution, and do not constitute a limitation to the present disclosure.

FIG. 1 is a schematic diagram of the sub-regions and temperature detection region of a heating lamp in a heat treatment device;

FIG. 2 is a distribution diagram of measurement points of target parameters in a measurement machine in the prior art;

FIG. 3 is a distribution diagram of measurement points according to an embodiment of the present disclosure; and

FIG. 4 is a schematic flow chart of a temperature control method according to an embodiment of the present disclosure.

### DETAILED DESCRIPTION

Hereinafter, descriptions to exemplary embodiments of the present disclosure are made with reference to the accompanying drawings, include various details of the embodiments of the present disclosure to facilitate understanding, and should be considered as merely exemplary. Therefore, those having ordinary skill in the art should realize, various changes and modifications may be made to the embodiments described herein, without departing from the scope of the present disclosure. Likewise, for clarity and conciseness, descriptions of well-known functions and structures are omitted in the following descriptions.

In practical applications, as the number of wafers passing through a reaction chamber of a thermal annealing device increases, a temperature sensor (such as a pyrometer) of the device will be offset or contaminated, and the accuracy of temperature measurement will be affected. On the other hand, the aging of the heating lamps in the thermal annealing device will also affect the actual temperature in the reaction chamber. Therefore, in order to produce qualified wafers for the device, it is necessary to perform temperature compensation on the thermal annealing device within the allowable temperature range so that the process temperature in the reaction chamber is maintained within a stable range (for example, the temperature deviation is less than 1° C.).

In the heat treatment process (i.e., thermal annealing process), the sensor (e.g., pyrometer) is usually used to detect the temperature in the reaction chamber according to the heating region in the heat treatment device during the annealing process. After the heat treatment process is completed, the semiconductor workpiece (such as wafer) is transported to a detection machine, to perform the target parameter detection on the semiconductor workpiece after the heat treatment. It is judged whether the parameter compensation is required for the heat treatment process machine based on the test result of the target parameter.

Since the semiconductor workpiece is detected in two different machines, and since the radius of the concentric circle for measuring the square resistivity and oxide film thickness on the wafer is inconsistent with the radius controlled by the lamp partition, the difference in the measurement point distributions of the two machines will cause the inaccuracy in calculating the temperature compensation. The temperature compensation value is prone to deviation. In practical applications, multiple repeated calculations are required to reduce the error of the temperature compensation, affecting the production efficiency.

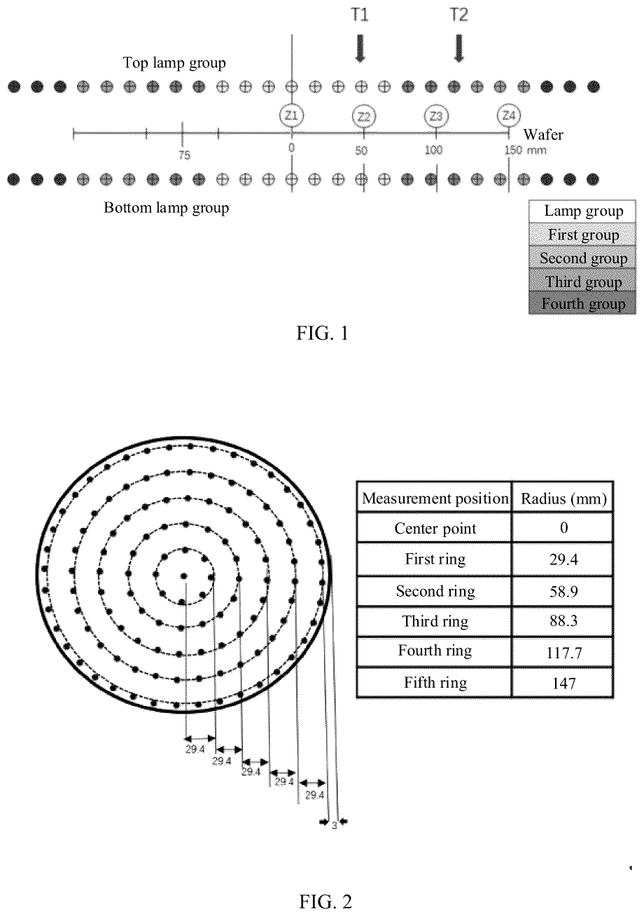

As shown in FIG. 1, in a heat treatment device, a plurality of heating elements are usually used for heating, for example, a top lamp group and a bottom lamp group are used for full radiation heating of a semiconductor workpiece (e.g., a wafer) to be processed. In the prior art, each lamp group can be divided into a plurality of regions, such as four regions Z1, Z2, Z3 and Z4, with the central axis of the wafer as the center, and these regions are controlled separately. The temperatures T1 and T2 in the reaction chamber are measured by setting a sensor, such as a pyrometer.

As shown in FIG. 2, the measuring points of the detection device (measurement machine) in the prior art are usually set to a center point and 5 concentric circles with equal spacing (29.4 mm) (3 mm is removed from the edge). For example, for the measurement in the manufacturing process of a 12-inch wafer, the current common measurement is 49-point or 121-point measurement; the 49-point measurement involves a center point and 5 concentric circles with equal spacing, and the 121-point measurement involves a center point and 5 concentric circles with equal spacing.

As can be seen from FIGS. 1 and 2 above, the region division of the lamp group of the heat treatment device does not match the radius of the concentric circle of the measurement point of the measurement machine. Therefore, the compensation data obtained based on the detection result of the measurement machine cannot accurately correspond to the control process parameter of the heat treatment device (such as the power of the lamp), thus leading to a compensation error or increasing the number of compensation times, thereby reducing the process efficiency. According to one aspect of the present disclosure, provided is a temperature control

method for semiconductor process, including: setting a first measurement point of a first point distribution in a first process device to measure a temperature in the first process device; and setting a second measurement point of a second point distribution in a second detection device to measure a target parameter; where the first point distribution includes a concentric circle-shaped dot matrix with unequal radial spacings; and the second point distribution has a concentric circle-shaped dot matrix corresponding to the first point distribution.

According to a specific embodiment, the temperature control method may further include:

obtaining a process temperature of each point of a tested semiconductor workpiece in the first point distribution under a standard process condition in the first process device;

detecting a target parameter of the tested semiconductor workpiece corresponding to the process temperature and determining a corresponding relationship between the process temperature and the target parameter in the second detection device;

detecting a target parameter of a semiconductor workpiece to be tested and comparing a measured value of the target parameter of the semiconductor workpiece to be tested with a set standard range of the target parameter in the second detection device;

calculating a deviation value of the target parameter if the measured value of the target parameter of the semiconductor workpiece to be tested exceeds the set standard range; and

calculating a temperature deviation value in each heating region from the deviation value of the target parameter according to the corresponding relationship.

The above corresponding relationship means that a rate of change is determined through a change in the corresponding target parameter measured in the second detection device when the process temperature in the first process device changes by 1° C.

According to a specific embodiment, under standard rapid annealing process conditions, such as a low pressure of 1 to 760 Torr, a process temperature of 200 to 1200° C., a process gas containing oxygen, nitrogen, oxygen and nitrogen, or oxygen and hydrogen, and a total gas flow rate of 1 to 60 SLM (Standard Liter per Minute), when the process temperature in the detection annealing machine changes by 1° C., the change in the square resistivity of the tested wafer detected in the measurement machine is 2 Ω·cm⁻², and then the rate of change is determined to be 2 Ω·cm⁻²·° C⁻¹. Here, the baseline value of the square resistivity of the wafer may be 160 Ω·cm⁻². After the wafer to be tested undergoes rapid annealing under set conditions in the annealing machine, the square resistivity of the wafer after annealing detected in the measurement machine is 170 Ω·cm⁻². Then the temperature value that needs to be supplemented is calculated as follows:

$$Δ T = ( 170 - 160 ) / 2 = 5 ° C .$$

That is, the temperature compensation of 5° C. is required.

According to another embodiment, the change in thickness of the surface oxide film of the wafer may also be detected in the measurement machine, and the change in thickness under a unit temperature change is determined as the rate of change in thickness. The deviation value of the thickness of the surface oxide film of the wafer to be tested relative to the set standard thickness value is tested and calculated, and the temperature compensation value can be obtained by dividing the deviation value by the rate of change in thickness.

Specifically, in the rapid thermal annealing device, the wafer rotates during the process, especially in the annealing device for wafers larger than 12 inches. In order to maintain the uniformity of the annealing temperature of the wafer, the heating lamps need to be controlled in different regions. The power of each region can be controlled independently to thereby achieve the adjustment of the temperature uniformity.

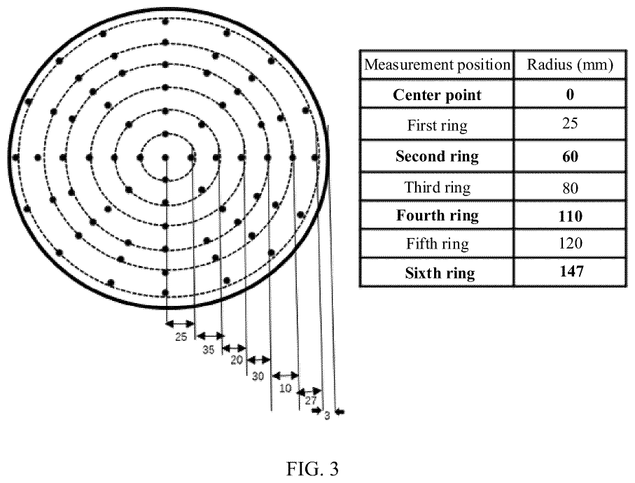

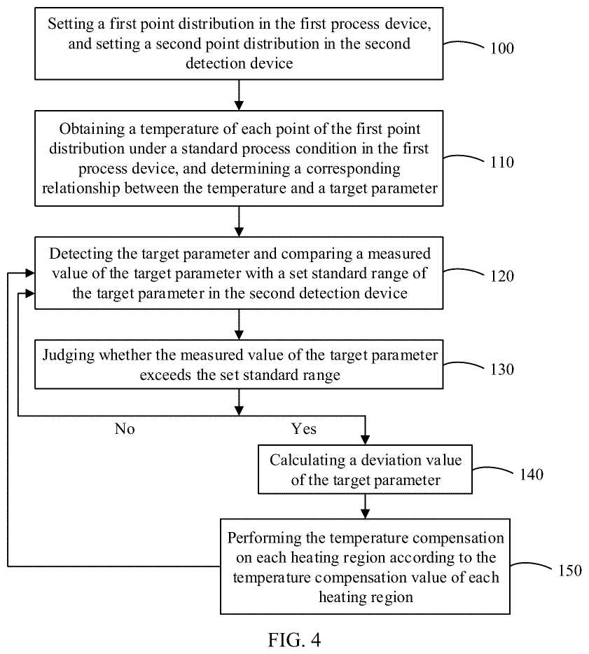

Specifically, referring to FIGS. 3 and 4, the temperature control method according to the present disclosure may include a measurement point setting step, a step of determining the corresponding relationship between the temperature of the first process device and the target parameter measured by the second detection device, and a parameter compensation step.

Specifically, the measurement point setting step 100 may include: setting a first point distribution in the first process device (for example, a thermal annealing device), and setting a second point distribution in the second detection device (for example, a detection machine for detecting the square resistivity or oxide film thickness). Here, the center point of the first point distribution is on the same vertical line as the center point of the heating elements (for example, a top heating lamp group and a bottom heating lamp group) of the first process device. Further, according to the region division of the heating element, the radius distance of the concentric circles of the point distribution is set accordingly, so that the concentric circles of the point distribution correspond to the corresponding regions of the heating element respectively, that is, the spacings of the concentric circles of the point distribution in the first process device are not equal.

According to one embodiment, as shown in FIG. 3, the semiconductor workpiece is a 12-inch wafer, and the heat treatment process is rapid thermal annealing process. At this time, the rapid thermal annealing device includes a plurality of heating lamp groups (such as a top heating lamp group and a bottom heating lamp group), and includes a plurality of heating regions (for example, 6 heating regions). According to the above temperature control method, the first point distribution is usually set to include a center point and 6 concentric circles with unequal spacings. Further, the spacings between adjacent concentric circles from the center point to the edge may be 25 mm, 35 mm, 20 mm, 30 mm, 10 mm and 27 mm sequentially (that is, the radii are 25 mm, 60 mm, 80 mm, 110 mm, 120 mm and 147 mm sequentially), with 3 mm excluded from the edge.

Correspondingly, the second point distribution in the detection machine may also be set to include a center point and 6 concentric circles with unequal spacings, and the spacings between adjacent concentric circles from the center point to the edge may be 25 mm, 35 mm, 20 mm, 30 mm, 10 mm and 27 mm sequentially (that is, the radii are 25 mm, 60 mm, 80 mm, 110 mm, 120 mm and 147 mm sequentially), with 3 mm excluded from the edge. That is, the second point distribution completely corresponds to the first point distribution, so the measurement data of the detection machine can more accurately reflect the uniformity of the heat treatment process.

According to another embodiment, in the rapid thermal annealing process of the wafer, the first process device (thermal annealing device) may include a plurality of heating elements, for example, a top heating lamp group and a bottom heating lamp group, and the heating lamp group may be divided into four regions (for example, referring to FIG. 1). The size of each region can be adjusted according to specific process conditions. Corresponding to the region division of the heating lamp group, the first point distribution in the first process device may include a center point and 3 concentric circles. Correspondingly, the spacings between adjacent concentric circles from the center point to the edge on the wafer may be 60 mm, 50 mm and 37 mm sequentially (that is, the radii arc 60 mm, 110 mm and 147 mm sequentially), with 3 mm excluded from the edge. In this process device, the machine does not directly test the process temperature, but instead senses the current or voltage value through a sensor, and obtains a temperature value through calculation. As the device is used or contaminated, the sensing value of the sensor is prone to drift or error, making the temperature sensed by the process device inaccurate.

In the second detection device, the second point distribution is performed, so that the measurement points of the second point distribution correspond to those of the first point distribution one by one, that is, include a center point and a plurality of concentric circles with different spacings. The second detection device can be used to perform the physical detection on the square resistivity or oxide film thickness of the semiconductor workpiece. Specifically, the average value of the parameter data measured at the measurement points on the same concentric circle is the parameter measurement value of this region.

According to one embodiment, for the rapid thermal annealing process of a 12-inch wafer, the four regions of the annealing device correspond to the positions of the wafer at 0, 60 mm, 110 mm and 147 mm, respectively; and therefore, the radii of the concentric circles are adjusted to 60 mm, 110 mm and 147 mm during measurement, and the compensation value of the temperature is preset after the independent analysis and calculation of the data of these concentric circles. The measurement values of other concentric circles can be adjusted appropriately as required to monitor the process.

Specifically, the number of points on the same concentric circle of the above point distribution can be set according to the process requirement, for example, may be a 49-dot matrix or a 121-dot matrix. For example, when the semiconductor workpiece processed is a 12-inch wafer, the first point distribution includes a center point, and a concentric circle-shaped 49-dot matrix or 121-dot matrix extending radially outward from the center point at distances of 25 mm, 60 mm, 80 mm, 110 mm, 120 mm and 147 mm respectively.

The corresponding relationship determining step 110 may include: determining a rate of change through a change in the target parameter (for example, square resistivity or oxide film thickness) detected in the second detection device when the process temperature in the first process device changes by 1° C.

According to a specific embodiment, the process temperature (sensed by a standard sensor) of each point of the tested semiconductor workpiece (tested wafer) in the first point distribution (for example, a center point and 3 concentric circles) under the standard process condition is obtained in the first process device (thermal annealing device). Then, in the second detection device (i.e., measurement machine), a target parameter (for example, square resistivity or oxide film thickness) of the tested semiconductor workpiece (tested wafer) is detected according to the measurement points of the second point distribution corresponding to the aforementioned first point distribution, and a corresponding relationship between the process temperature and the target parameter is determined. This corresponding relationship, as described above, refers to determining the rate of change by the change in the corresponding target parameter (i.e., square resistivity or oxide film thickness) measured in the second detection device when the process temperature in the first process device changes by 1° C.

According to one embodiment, in the rapid thermal annealing process, the target parameter is the square resistivity or the thickness of the surface oxide film of the wafer, and the rate of change thereof relative to the process temperature in the first process device may be 2.

Referring to FIG. 4, the temperature control method further includes: comparing the measured value of the target parameter with a set standard range of this parameter (120), judging whether the measured value of the target parameter exceeds the set standard range (130), calculating a deviation value of the measured value of the target parameter relative to the standard range (140) if the measured value exceeds the set standard range, calculating and setting a temperature compensation value of a corresponding heating region according to the calculated deviation value and the corresponding relationship obtained above, and performing the temperature compensation on each heating region (150). If the measured value does not exceed the set standard range, there is no need to perform the temperature compensation, and the target parameter detection and comparison of the wafer after thermal annealing (120) continues.

According to one embodiment, the temperature compensation step is performed by adjusting the power of the heating element of each heating region.

The temperature control method provided in the present disclosure is a method of utilizing the accurate test parameters of the subsequent detection machine to perform the temperature compensation on the process treatment machine that does not perform the accurate temperature measurement through the predetermined corresponding relationship, thereby improving the accuracy of temperature compensation. Specifically, the measurement points of the detection machine of the method of the present disclosure is set to include a center point and concentric circles with unequal spacings, and these concentric circles correspond to the heating regions of the process device one by one, which can accurately reflect the changes in the process conditions, thereby accurately adjusting the process.

Taking a rapid thermal annealing device as an example, the heating lamp is divided into four heating regions. During the process, the heating power can be adjusted and controlled for one or several regions individually to achieve the uniform evenness. For large-scale mass production devices, during a device maintenance cycle, due to the aging of the lamps and the drift of the precise temperature of the temperature measurement point, it is necessary to preset a temperature compensation value for each heating region to thereby achieve the uniform temperature. The positions of the four regions corresponding to the wafer are 0 mm, 60 mm, 110 mm and 147 mm respectively; and therefore, the radii of the concentric circles of the measurement points are adjusted to 60 mm, 110 mm and 147 mm during measurement, and the compensation value of the temperature is preset after the independent analysis and calculation of the data of these concentric circles. Further, the measurement values of other concentric circles can be set and adjusted appropriately according to the process requirements, so as to monitor the entire process, improve the stability of the process, and improve the production efficiency.

It should be understood that, the steps may be reordered, added or removed by using the various forms of the flows described above. For example, the steps recorded in the present disclosure can be performed in parallel, in sequence, or in different orders, as long as a desired result of the technical scheme disclosed in the present disclosure can be realized, which is not limited herein.

The foregoing specific implementations do not constitute a limitation on the protection scope of the present disclosure. Those having ordinary skill in the art should understand that, various modifications, combinations, sub-combinations and substitutions may be made according to a design requirement and other factors. Any modification, equivalent replacement, improvement or the like made within the principle of the present disclosure shall be included in the protection scope of the present disclosure.

What is claimed is:

1. A temperature control method for semiconductor process, comprising:
setting a first measurement point of a first point distribution in a first process device to measure a temperature in the first process device; and
setting a second measurement point of a second point distribution in a second detection device to measure a target parameter;
wherein the first point distribution comprises a concentric circle-shaped dot matrix with unequal radial spacings; and
the second point distribution has a concentric circle-shaped dot matrix corresponding to the first point distribution.

2. The temperature control method of claim 1, wherein concentric circles of the first point distribution correspond to heating regions of the first process device one by one; and concentric circles of a measurement dot matrix correspond to the plurality of heating regions respectively.

3. The temperature control method of claim 2, further comprising:
obtaining a process temperature of each point of a tested semiconductor workpiece in the first point distribution under a standard process condition in the first process device;
detecting a target parameter of the tested semiconductor workpiece corresponding to the process temperature and determining a corresponding relationship between the process temperature and the target parameter in the second detection device;
detecting a target parameter of a semiconductor workpiece to be tested and comparing a measured value of the target parameter of the semiconductor workpiece to be tested with a set standard range of the target parameter in the second detection device;
calculating a deviation value of the target parameter if the measured value of the target parameter of the semiconductor workpiece to be tested exceeds the set standard range;
calculating a temperature deviation value in each heating region from the deviation value of the target parameter according to the corresponding relationship; and
performing temperature compensation on each heating region according to the temperature deviation value in each heating region.

4. The temperature control method of claim 3, wherein the temperature compensation is performed by adjusting power of a heating element of each heating region.

5. The temperature control method of claim 1, wherein the target parameter is a square resistivity or a thickness of a surface oxide film of the semiconductor workpiece.

6. The temperature control method of claim 1, wherein the first process device is a rapid thermal annealing device, and the semiconductor workpiece processed is a wafer.

7. The temperature control method of claim 6, wherein the rapid thermal annealing device comprises a plurality of heating lamp groups and comprises a plurality of heating regions.

8. The temperature control method of claim 3, wherein the corresponding relationship determines a rate of change through a change in the target parameter detected in the second detection device when the process temperature in the first process device changes by 1° C.

9. The temperature control method of claim 8, wherein the target parameter is a square resistivity or a thickness of a surface oxide film of a wafer, and a rate of change relative to the process temperature in the first process device is 2.

10. The temperature control method of claim 1, wherein when the semiconductor workpiece processed is a 12-inch wafer, the first point distribution comprises a center point, and a concentric circle-shaped 49-dot matrix or 121-dot matrix extending radially outward from the center point at distances of 25 mm, 60 mm, 80 mm, 110 mm, 120 mm and 147 mm respectively.
